(19) United States
(12) Patent Application Publication
(10) Pub. No.: US 2026/0090144 A1
(43) Pub. Date: Mar. 26, 2026

(54) SEMICONDUCTOR LIGHT-EMITTING DEVICE AND LIGHT EMITTING APPARATUS INCLUDING THE SAME

(71) Applicant: XIAMEN SAN'AN OPTOELECTRONICS CO., LTD., Xiamen (CN)

(72) Inventors: Tongwei YAN, Xiamen (CN); Yanchun CHEN, Xiamen (CN); Shaohua HUANG, Xiamen (CN); Chien-yao TSENG, Xiamen (CN); CHI-LUN CHOU, Xiamen (CN); Chiming TSAI, Xiamen (CN); CHUNG-YING CHANG, Xiamen (CN)

(21) Appl. No.: 19/404,223

(22) Filed: Dec. 1, 2025

Related U.S. Application Data
(63) Continuation-in-part of application No. PCT/CN2023/097994, filed on Jun. 2, 2023.

(51) Int. Cl. H10H 20/81; H10H 20/816; H10H 20/821; H10H 20/825

(52) U.S. Cl. CPC H10H 20/8215; H10H 20/8162; H10H 20/821; H10H 20/8252

(57) ABSTRACT

A semiconductor light-emitting device includes a semiconductor stack, which includes an N-type semiconductor layer, a light-emitting layer and a P-type semiconductor layer. The semiconductor stack contains an n-type impurity that has a concentration profile along a thickness direction. The concentration profile includes a first segment, a second segment and a third segment. The N-type semiconductor layer has an X region, a Y region, and a Z region. The first segment corresponds to the X region and indicates a first concentration of the n-type impurity in the X region, the third segment corresponds to the Y region and indicates a second concentration of the n-type impurity in the Y region, and the second segment corresponds to the Z region and indicates a third concentration of the n-type impurity in the Z region. A light-emitting apparatus including the aforesaid semiconductor light-emitting device is also provided.

### CROSS-REFERENCE TO RELATED APPLICATION

This application is a continuation-in-part (CIP) of International Application No. PCT/CN2023/097994, filed on Jun. 2, 2023, the entire disclosure of which is incorporated by reference herein.

### FIELD

The disclosure relates to a semiconductor device, and more particularly to a semiconductor light-emitting device and a light-emitting apparatus including the same.

### BACKGROUND

Semiconductor light-emitting devices are inorganic semiconductor devices that emit light through the recombination of electrons and holes. Among them, ultraviolet light-emitting devices have broad application prospects in fields such as sterilization and disinfection, polymer curing, biochemical detection, non-line-of-sight communication, and special lighting.

In one of the ultraviolet light-emitting devices, AlGaN is often used in a barrier layer of a quantum well structure, and the Al content in the barrier layer may be increased to raise an overall Al content in the ultraviolet light-emitting device. However, for an n-type or p-type doped AlGaN material, an increase in the average Al content may lead to a degradation in crystal quality and an increase in defect density, which, in turn, leads to elevated leakage current and malfunction of the ultraviolet light-emitting device.

### SUMMARY

Therefore, in a first aspect, the present disclosure provides a semiconductor light-emitting device, which can alleviate at least one of the drawbacks of the prior art.

The semiconductor light-emitting device includes a semiconductor stack which includes an N-type semiconductor layer, a light-emitting layer and a P-type semiconductor layer. The N-type semiconductor layer, the light-emitting layer and the P-type semiconductor layer are stacked in such an order in a thickness direction.

At least a part of the semiconductor stack contains an n-type impurity, and the n-type impurity has a concentration profile along the thickness direction. The concentration profile includes a first segment, a second segment and a third segment. The N-type semiconductor layer has an X region which is distal from the light-emitting layer, a Y region which is proximate to the light-emitting layer, and a Z region which is connected between the X region and the Y region.

The first segment corresponds to the X region and indicates a first concentration of the n-type impurity in the X region, and the first concentration of the n-type impurity is greater than or equal to 5×10¹⁸ atoms/cm³.

At least a part of the third segment corresponds to the Y region and indicates a second concentration of the n-type impurity in the Y region, and the second concentration of the n-type impurity is less than 1×10¹⁸ atoms/cm³.

The second segment corresponds to the Z region and indicates a third concentration of the n-type impurity in the Z region, and the third concentration of the n-type impurity ranges from the first concentration of the n-type impurity to the second concentration of the n-type impurity.

A thickness of the Y region is greater than or equal to 10 nm.

In a second aspect, the present disclosure provides a light-emitting apparatus, which can alleviate at least one of the drawbacks of the prior art. The light-emitting apparatus includes the aforesaid semiconductor light-emitting device.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a cross-sectional view of a semiconductor light-emitting device according to a first embodiment of the present disclosure.

FIG. 2 is a graph showing the relationship between elemental concentration or ion intensity and depth for a portion of the semiconductor light-emitting device according to the first embodiment of the present disclosure.

FIG. 3 is a cross-sectional view of a portion of the semiconductor light-emitting device according to the first embodiment of the present disclosure.

FIG. 4 is a cross-sectional view of a semiconductor light-emitting device according to a second embodiment of the present disclosure.

FIG. 5 is a graph showing the relationship between elemental concentration or ion intensity and depth for a portion of a semiconductor light-emitting device according to a third embodiment of the present disclosure.

FIG. 6 is a graph showing the relationship between elemental concentration or ion intensity and depth for a portion of a semiconductor light-emitting device according to a fourth embodiment of the present disclosure.

FIG. 7 is a graph showing the relationship between elemental concentration or ion intensity and depth for a portion of a semiconductor light-emitting device according to a fifth embodiment of the present disclosure.

FIG. 8 is a cross-sectional view of a portion of the semiconductor light-emitting device according to the fifth embodiment of the present disclosure.

FIG. 9 is a cross-sectional view of a semiconductor light-emitting device according to a sixth embodiment of the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

The composition and dopant(s) of each layer in a light-emitting device of the present disclosure can be analyzed by any suitable means, such as by using a secondary ion mass spectrometer (SIMS). The thickness of each layer in the light-emitting device of the present disclosure can be analyzed by any suitable method, such as by using a transmission electron microscopy (TEM) or a scanning electron microscopy (SEM), in conjunction with, for example, the depth position of such a layer on a SIMS spectrum.

The relative intensities of III-group elements such as aluminum (Al), indium (In), and gallium (Ga) can be obtained from a SIMS compositional profile analysis of a general epitaxial structure or from an elemental analysis of an energy-dispersive X-ray spectroscopy (EDX) in a TEM. In addition, the bandgap energy can be determined by intensities of the two elements, i.e., Al and In. That is, the higher the Al content, the higher the bandgap energy; the higher the In content, the lower the bandgap energy.

In the present disclosure, unless otherwise specified, the term “peak segment” refers to a line profile that includes two line segments with opposite slopes, i.e., one line segment has a positive slope and the other line segment has a negative slope. The term “peak value” refers to the highest concentration value between the two line segments with opposite slopes of the peak segment.

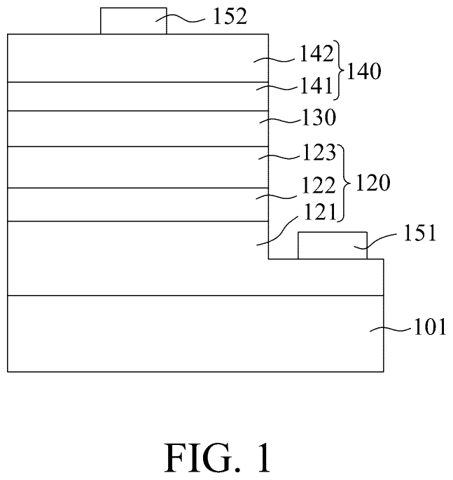

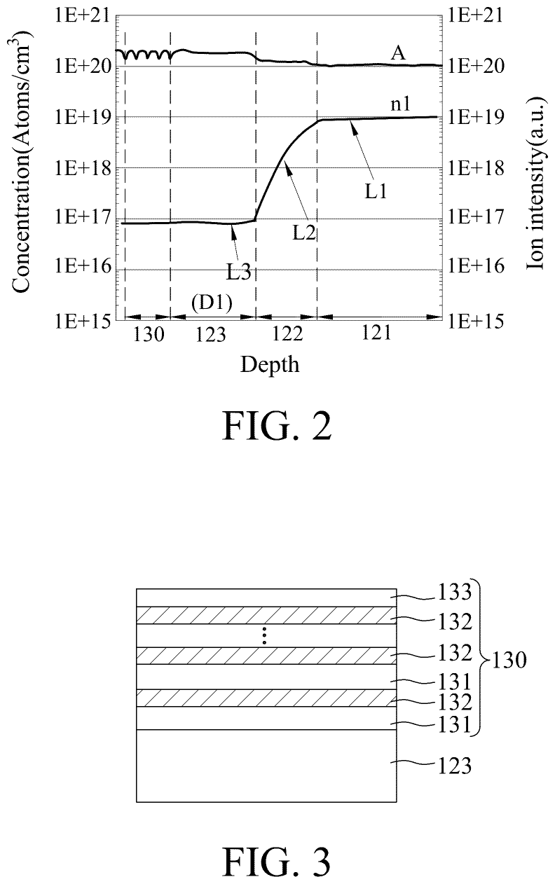

FIG. 1 is a cross-sectional view of a semiconductor light-emitting device according to a first embodiment of the present disclosure. FIG. 2 is a graph showing the relationship between elemental concentration or ion intensity and depth for a portion of the semiconductor light-emitting device according to the first embodiment of the present disclosure. This graph may be obtained using a SIMS. In the first embodiment of the present disclosure, the semiconductor light-emitting device has a face-up structure; however, the semiconductor light-emitting device of the present disclosure is not limited thereto. Alternatively, the semiconductor light-emitting device may have a vertical structure or a flip-chip structure. FIG. 1 shows a schematic diagram of the structure of the semiconductor light-emitting device which has a semiconductor stack including, from bottom to top, an N-type semiconductor layer 120 that has a first surface and a second surface opposite to the first surface, a light-emitting layer 130, and a P-type semiconductor layer 140 deposited on a substrate 101. That is, the N-type semiconductor layer 120, the light-emitting layer 130 and the P-type semiconductor layer 140 are stacked in such an order in a thickness direction from bottom to top. Additionally, the N-type semiconductor layer 120 has an X region which is distal from the light-emitting layer 130, a Y region which is proximate to the light-emitting layer 130, and a Z region which is connected between the X region and the Y region. The semiconductor stack may be formed by chemical vapor deposition (CVD) (e.g., metal-organic chemical vapor deposition (MOCVD), plasma-enhanced chemical vapor deposition (PECVD), etc.), molecular beam epitaxy (MBE), hydride vapor phase epitaxy (HVPE), or the like, but methods for forming such a semiconductor stack are not limited thereto. In some embodiments, the substrate 101 may be thinned or removed. Furthermore, the semiconductor light-emitting device may also include a first electrode 151 and a second electrode 152. The first electrode 151 is electrically connected to the N-type semiconductor layer 120, and the second electrode 152 is in ohmic contact with the P-type semiconductor layer 140.

In some embodiments, the semiconductor stack of the semiconductor light-emitting device is made of an AlGaInN-based semiconductor material. The N-type semiconductor layer 120 is used to provide electrons to the light-emitting layer 130, and may include a semiconductor material represented by the chemical formula InₓAl_{y}Ga_{1-x-y}N, where 0≤x≤1, 0≤y≤1, and 0≤x+y ≤1. The semiconductor material for the N-type semiconductor layer 120 may be, for example, GaN, AlN, AlGaN, InGaN, InN, InAlGaN, or AlInN. The N-type semiconductor layer 120 may be doped with an n-type dopant, such as Si, Ge, Sn, Se, or Te. When the semiconductor light-emitting device is an ultraviolet light-emitting device, the N-type semiconductor layer 120 may include AlGaN. Referring to FIG. 2, at least a part of the semiconductor stack contains an n-type impurity, and the n-type impurity has a concentration profile (n1) along the thickness direction. The concentration profile (n1) includes a first segment (L1), a second segment (L2), and a third segment (L3). The first segment (L1) corresponds to the X region and indicates a first concentration of the n-type impurity in the X region, which is greater than or equal to 5×10¹⁸ atoms/cm³. At least a part of the third segment (L3) corresponds to the Y region and indicates a second concentration of the n-type impurity in the Y region, which is less than 1×10¹⁸ atoms/cm³. A thickness (D1) of the Y region is greater than or equal to 10 nm. The second segment (L2) corresponds to the Z region and indicates a third concentration of the n-type impurity in the Z region, which ranges from the first concentration of the n-type impurity to the second concentration of the n-type impurity. In other words, the second segment (L2) connects the first segment (L1) and the third segment (L3), and exhibits n-type impurity concentration values that decrease from the first concentration of the n-type impurity to the second concentration of the n-type impurity. In some embodiments, the N-type semiconductor layer 120 is made of an AlGaN-based material, and the first concentration of the n-type impurity is greater than or equal to 5×10¹⁸ atoms/cm³ and less than 5×10²⁰ atoms/cm³. Controlling the first concentration of the n-type impurity within the aforementioned range ensures a good ohmic contact interface and allows for better control over the crystal quality of the N-type semiconductor layer 120. An excessively high concentration of the n-type impurity, however, may affect the crystal quality of the semiconductor stack. In some embodiments, the second concentration of the n-type impurity is not greater than 5×10¹⁷ atoms/cm³, and the thickness (D1) of the Y region is greater than or equal to 10 nm. In some other embodiments, the thickness (D1) of the Y region is greater than 20 nm and less than 250 nm, e.g., the thickness (D1) may range from 50 nm to 150 nm. Within the aforesaid thickness range, a better balance between the anti-aging ability and photoelectric properties of the semiconductor light-emitting device may be achieved.

In some embodiments, a part of the third segment (L3) corresponds to at least a portion of the light-emitting layer 130, and a concentration of the n-type impurity in the at least a portion of the light-emitting layer 130 is less than or equal to 5×10¹⁶ atoms/cm³. In some embodiments, the third segment (L3) corresponds to a region of the semiconductor stack having a thickness greater than or equal to 50 nm and less than 300 nm. It may be said that a sum of the thickness (D1) of the Y region and a thickness of the at least a portion of the light-emitting layer 130 is greater than or equal to 50 nm and less than 300 nm. In some embodiments, a part of the third segment (L3) exhibits a concentration of the n-type impurity less than or equal to 5×10¹⁶ atoms/cm³. It can be said that a part of the concentration profile corresponds to a region from the N-type semiconductor layer 120 toward the P-type semiconductor layer 140, and indicates a concentration of the n-type impurity in the region that is less than or equal to 5×10¹⁶ atoms/cm³, and the region has a thickness greater than or equal to 50 nm and less than 300 nm.

In other embodiments, the N-type semiconductor layer 120 includes a first layer 121, a second layer 122, and a third layer 123. The first layer 121 is an Alₓ₁Ga₁₋ₓ₁N semiconductor layer and has a doping concentration of the n-type impurity greater than or equal to 5×10¹⁸ atoms/cm³. The first layer 121, with a sufficient doping concentration of the n-type impurity and a sufficient thickness (usually greater than or equal to 500 nm), provides electrons and forms an ohmic contact with the first electrode 151. The second layer 122 is disposed above the first layer 121, and is an Alₓ₂Ga₁₋ₓ₂N semiconductor layer. In still other embodiments, the second layer 122 has a doping concentration of the n-type impurity less than that of the first layer 121 (i.e., the doping concentration of the n-type impurity in the first layer 121 is greater than the doping concentration of the n-type impurity in the second layer 122), and has a bandgap energy higher than a bandgap energy of the first layer 121. By appropriately adjusting the doping concentration of the n-type impurity in the second layer 122 and the bandgap energy of the same, the light absorption effect of the semiconductor stack can be eliminated, which facilitates improvement of the emission efficiency of the semiconductor light-emitting device, particularly for a light-emitting device emitting light with a short wavelength (e.g., UV light). In addition, by controlling the doping concentration of the n-type impurity in the second layer 122 to be lower than the doping concentration of the n-type impurity in the first layer 121, when a current is injected into the first layer 121 through the first electrode 151, current spreading may occur in the second layer 122, which results in the formation of a two-dimensional electron gas and hence leads to an enhancement of the internal quantum efficiency of the semiconductor light-emitting device. In yet other embodiments, the second layer 122 has a thickness ranging from 20 nm to 100 nm, which allows for better current spreading. The third layer 123 is disposed above the second layer 122, is proximate to the light-emitting layer 130, has a doping concentration of the n-type impurity less than 1×10¹⁸ atoms/cm³, and has a thickness (D1) greater than or equal to 10 nm. In some embodiments, the second layer 122 disposed between the first layer 121 and the third layer 123 has the doping concentration of the n-type impurity less than that of the first layer 121 and greater than that of the third layer 123. The third layer 123 is located between the second layer 122 and the light-emitting layer 130, and has a stress-relieving function. In some embodiments, a bandgap energy of the third layer 123 is higher than a bandgap energy of the light-emitting layer 130, and the light-emitting layer 130 emits light having a wavelength ranging from 340 nm to 425 nm. In some other embodiments, the third layer 123 is a superlattice structure containing Alₓ₃Ga₁₋ₓ₃N. The superlattice structure includes periodic units each generally having at least two thin layers of different materials. The thin layers may be nitride-based semiconductor layers. In an embodiment, the superlattice structure includes AlGaN/GaN periodic units. In still another embodiment, the superlattice structure includes at least one periodic unit having multiple layers, for example, GaN/AlGaN/AlN, InGaN/AlGaN/AlN, or InGaN/GaN/AlN. The periodic units with high bandgap energy may modulate a radiative recombination region, thereby enhancing the recombination efficiency of the light-emitting layer 130 and thus improving brightness. In addition, the periodic units with high bandgap energy may prevent leakage caused by thermally excited holes or electrons that acquire excess energy, thus enhancing brightness stability under high-temperature operation. The hot/cold (H/C) factor value may reach 70% or higher. In some embodiments, among the Alₓ₁Ga₁₋ₓ₁N of the first layer 121, the Alₓ₂Ga₁₋ₓ₂N of the second layer 122, and the Alₓ₃Ga₁₋ₓ₃N of the third layer 123, x1<x2<x3. In addition, the superlattice structure 123 has a concentration of the n-type impurity which varies along the thickness direction and decreases to less than 5×10¹⁶ atoms/cm³ at a side of the superlattice structure 123 proximate to the light-emitting layer 130.

In this embodiment, referring to FIG. 2, the first layer 121 may be the X region that has the first segment (L1) of the concentration profile (n1), the second layer 122 may be the Y region that has the second segment (L2) of the concentration profile (n1), and the third layer 123 may be the Z region that has the third segment (L3) of the concentration profile (n1).

In some embodiments, the second layer 122 has a concentration of the n-type impurity that varies along the thickness direction. Specifically, the concentration of the n-type impurity in the second layer 122 decreases from the first concentration of the n-type impurity indicated by the first segment (L1) to the second concentration of the n-type impurity indicated by the second segment (L2). By varying the concentration of the n-type impurity, on the one hand, current spreading function of the second layer 122 can be ensured, on the other hand, better control over the thickness where the second concentration of the n-type impurity is distributed within the semiconductor stack can be achieved. In this embodiment, the second concentration of the n-type impurity is not greater than 5×10¹⁷ atoms/cm³, and has a distribution thickness (also denoted as D1) in the N-type semiconductor layer 120 greater than or equal to 20 nm and less than 250 nm. That is to say, the third layer 123 has a thickness (also denoted as D1) greater than or equal to 20 nm and less than 250 nm. By controlling the third layer 123, which is proximate to the light-emitting layer 130, to have a lower doping concentration of the n-type impurity, the reverse leakage current of the semiconductor light-emitting device can be suppressed. In other embodiments, the second concentration of the n-type impurity is not greater than 1×10¹⁷ atoms/cm³, and the thickness (D1) of the third layer 123 is not greater than 200 nm, which helps to strike a balance between the forward voltage characteristics of the semiconductor light-emitting device and the suppression of reverse leakage current. In still other embodiments, the second concentration of the n-type impurity is less than 1×10¹⁷ atoms/cm³.

Furthermore, FIG. 2 also shows a curve (A) (hereinafter referred to as “Al ion intensity curve (A)”) which illustrates the relationship between the ion intensity of the element Al (or Al ion intensity) and the depth thereof in a portion of the semiconductor light-emitting device of this embodiment, and which is obtained using a SIMS. In this embodiment, the Al ion intensity in the N-type semiconductor layer 120 increases layer by layer along the thickness direction. Specifically, the third layer 123 (containing the Alₓ₃Ga₁₋ₓ₃N) has the highest Al ion intensity, the second layer 122 (the Alₓ₂Ga₁₋ₓ₂N semiconductor layer) ranks second in terms of Al ion intensity, and the first layer 121 (the Alₓ₁Ga₁₋ₓ₁N semiconductor layer) has the lowest Al ion intensity, i.e., x3>x2>x1. The lower Al content in the first layer 121 is advantageous for achieving a good ohmic contact and forming a higher concentration of the n-type impurity therein. Additionally, the highest Al content in the third layer 123 may increase the bandgap energy thereof, which facilitates carrier confinement within the light-emitting layer 130 and thus enhances the internal quantum efficiency of the semiconductor light-emitting device. Furthermore, by controlling the second concentration of the n-type impurity in the third layer 123 to be less than or equal to 5×10¹⁷ atoms/cm³, the resistivity of the third layer 123 may be increased, thereby avoiding the occurrence of reverse leakage current under a high current.

The light-emitting layer 130 is formed on the N-type semiconductor layer 120. The light-emitting layer 130 may contain a Group III-V semiconductor material and may be formed to have a single-quantum-well structure or multiple-quantum-well structure, a quantum wire structure, a quantum dot structure, etc. In the semiconductor light-emitting device of this embodiment, e.g., a light-emitting diode, the light-emitting layer 130 may be represented by the chemical formula InₘAlₙGa₁₋ₘ₋ₙN (0≤m≤1, 0≤n≤1, and 0≤m+n≤1). The light-emitting layer 130 may have a single-quantum-well structure or a multiple-quantum-well structure; for example, the light-emitting layer 130 may include one or more barrier layers 131 and one or more well layers 132 disposed between the barrier layers 131. As shown in FIG. 3, in an embodiment, multiple well layers 132 and multiple barrier layers 131 may be alternately arranged, and the number of the well layers 132 or the barrier layers 131 may range from 3 to 8. Each of the well layers 132 may be made of a material having a bandgap energy less than that of each of the barrier layers 131. That is, the bandgap energy (Eg1) of the well layers 132 and the bandgap energy (Eg2) of the barrier layers 131 may satisfy Eg1<Eg2. As the Al content in the well layers 132 increases, the bandgap energy becomes more adjustable, the lattice constant increases, the luminous efficiency increases, and the wavelength of emitted light shortens. In this embodiment, a concentration of the n-type impurity in the light-emitting layer 130 is less than or equal to 5×10¹⁷ atoms/cm³. In some embodiments, a concentration of the n-type impurity in the light-emitting layer 130 is less than 1×10¹⁷ atoms/cm³. Controlling the concentration of the n-type impurity in the light-emitting layer 130 may help to further improve the anti-aging ability of the semiconductor light-emitting device. When the concentration of the n-type impurity in the light-emitting layer 130 exceeds 5×10¹⁷ atoms/cm³, light decay of the semiconductor light-emitting device accelerates, particularly under a high current, where more severe light decay may occur.

The wavelength of light emitted from the semiconductor light-emitting device may be determined by the composition and thickness of the light-emitting layer 130. In other embodiments, a thickness ratio of one of the well layers 132 to one of the barrier layers 131 ranges from 1:1.7 to 1:2, thus not only allowing for production of an ultraviolet (UV) light that has a wavelength ranging from 340 nm to 425 nm, but also improving the internal quantum efficiency.

In some embodiments, the light-emitting layer 130 has a top-most barrier layer 133, which has a thickness not less than 3 nm and not greater than 40 nm. If the thickness of the top-most barrier layer 133 is less than 3 nm, a leakage current is likely to occur. The top-most barrier layer 133 contains InⱼAlₖGa₍₁₋ⱼ₋ₖ₎N, where 0≤j≤1 and 0≤k≤1. In an embodiment, a material of the top-most barrier layer 133 is the same as a material of one of the other barrier layers 131. In some embodiments, the thickness of the top-most barrier layer 133 is greater than a thickness of one of the other barrier layers 131. In some other embodiments, the thickness of the top-most barrier layer 133 is greater than a thickness of each of the barrier layers 131.

The P-type semiconductor layer 140 is disposed above the light-emitting layer 130, and includes an electron blocking layer 141 and a hole injection layer 142. The electron blocking layer 141 is disposed between the light-emitting layer 130 and the hole injection layer 142, is made of a semiconductor material represented by the chemical formula In_{z}Al_{w}Ga_{1-z-w}N (0≤z≤1, 0≤w≤1, and 0≤z+w≤1), and has a lattice constant greater than a lattice constant of the hole injection layer 142. In some embodiments, a bandgap energy of the hole injection layer 142 is lower than the bandgap energy of the light-emitting layer 130. In an embodiment where the semiconductor light-emitting device is an ultraviolet light-emitting device, the electron blocking layer 141 includes AlGaN. The electron blocking layer 141 may have a bandgap energy higher than a bandgap energy of the light-emitting layer 130. When a high current is applied, the electron blocking layer 141 prevents electrons injected from the N-type semiconductor layer 120 into the light-emitting layer 130 from flowing into the hole injection layer 142 without recombination in the light-emitting layer 130, thereby increasing the probability of recombination of electrons and holes in the light-emitting layer 130 and thus preventing current leakage.

In some embodiments, in the chemical formula In_{z}Al_{w}Ga_{1-z-w}N of the electron blocking layer 141, 0≤z≤0.05 and 0.05≤w≤1. If w is less than 0.05, the electrostatic discharge protection capability of the semiconductor light-emitting device may deteriorate. The electron blocking layer 141 can further enhance the luminous efficiency of the semiconductor light-emitting device. In some embodiments, a concentration of a p-type impurity in the electron blocking layer 141 is less than or equal to 5×10¹⁹ atoms/cm³. In some other embodiments, the concentration of the p-type impurity in the electron blocking layer 141 is less than or equal to 2×10¹⁹ atoms/cm³ and greater than or equal to 5×10¹⁷ atoms/cm³. When the concentration of the p-type impurity in the electron blocking layer 141 is less than 5×10¹⁷ atoms/cm³, the voltage of the semiconductor light-emitting device may increase. In an embodiment, the concentration of the p-type impurity in the electron blocking layer 141 is controlled between 2×10¹⁹ atoms/cm³ and 1×10¹⁸ atoms/cm³, which is beneficial for controlling the voltage of the semiconductor light-emitting device and enables better control of the concentration of the p-type impurity in the light-emitting layer 130, thereby providing the semiconductor light-emitting device with excellent aging resistance.

The hole injection layer 142 is formed on the electron blocking layer 141, may be made of a semiconductor compound, and is used to inject holes into the light-emitting layer 130. The hole injection layer 142 may be made of a semiconductor material represented by the chemical formula In_{c}Al_{d}Ga_{1-c-d}N (0≤c≤1, 0≤d≤1, and 0≤c+d≤1), which may be, for example, GaN, AlN, AlGaN, InGaN, InN, InAlGaN, or AlInN, and may be doped with a p-type dopant (or p-type impurity), such as Mg, Zn, Ca, Sr, or Ba. In an embodiment where the semiconductor light-emitting device is an ultraviolet light-emitting device, the hole injection layer 142 may include AlGaN. In an embodiment, a concentration of the p-type impurity in the hole injection layer 142 is less than or equal to 1×10²⁰ atoms/cm³. Furthermore, a contact layer (not shown) may be formed on the hole injection layer 142. The contact layer may be a highly-doped p-type GaN layer or a highly-doped p-type AlGaN layer. For instance, the contact layer may be a highly-doped p-type AlGaN layer having a p-type doping concentration greater than 1×10²⁰ atoms/cm³, which is beneficial for forming a good ohmic contact with an electrode, e.g., the second electrode 152.

In the semiconductor light-emitting device of this embodiment, by controlling the doping concentration of the n-type impurity in the third layer 123 and the concentration of the n-type impurity in the light-emitting layer 130 to be less than or equal to 5×10¹⁷ atoms/cm³, a region formed between the N-type semiconductor layer 120 and the P-type semiconductor layer 140 is allowed to be free of excess doping, thereby reducing the likelihood of leakage current.

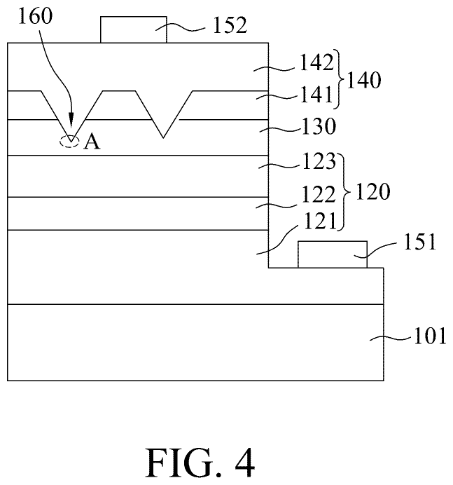

FIG. 4 is a cross-sectional view of a semiconductor light-emitting device according to a second embodiment of the present disclosure which has a structure similar to that of the first embodiment. Unlike the semiconductor light-emitting device shown in FIG. 1, in the semiconductor light-emitting device of this embodiment, the electron blocking layer 141 has at least one V-shaped pit 160 with a vertex (A) pointing towards the light-emitting layer 130, and the hole injection layer 142 fills the at least one V-shaped pit 160. The at least one V-shaped pit 160 may extend into the light-emitting layer 130, and hence a part of the at least one V-shaped pit 160 is formed in the light-emitting layer 130, which may prevent electrons or holes injected into the light-emitting layer 130 from being captured by non-radiative recombination centers such as dislocations, thereby facilitating the suppression of non-radiative recombination within the light-emitting layer 130. Furthermore, the position of the vertex (A) (or a bottom point) of the at least one V-shaped pit 160 is not lower than an initial growth position of the light-emitting layer 130 (i.e., a bottom surface of one of the barrier layers 131 or one of the well layers 132 that is most proximate to the N-type semiconductor layer 120). In some embodiments, the vertex (A) is located within the light-emitting layer 130, which lowers the leakage current path in the semiconductor stack and enhances the luminous efficiency of the semiconductor light-emitting device. Since at least a portion of the V-shaped pit 160 is located in the light-emitting layer 130 and the V-shaped pit 160 is filled with the hole injection layer 142, controlling a depth of the V-shaped pit 160 is beneficial for controlling the concentration of the p-type impurity in the light-emitting layer 130. In some embodiments, the V-shaped pit 160 has a top opening which is opposite to the vertex (A). The top opening has a diameter/width less than or equal to 160 μm, and the depth of the V-shaped pit 160 is less than 120 μm, which allows for better control of the concentration of the p-type impurity in the light-emitting layer 130 to be less than 5×10¹⁷ atoms/cm³, thereby further improving the optoelectronic performance of the semiconductor light-emitting device.

In some embodiments, the hole injection layer 142 has a bandgap energy (Eg5) that is higher than a bandgap energy (Eg1) of the well layers 132. In some other embodiments, the bandgap energy (Eg5) of the hole injection layer 142 is lower than a bandgap energy (Eg2) of one of the barrier layers 131. In an embodiment where the semiconductor light-emitting device is an ultraviolet light-emitting device, the bandgap energy of a semiconductor layer is usually increased to reduce light absorption of the same. By adjusting the Al content in the semiconductor layer, the bandgap energy thereof can be modified; however, high Al content in the semiconductor layer is unfavorable for filling of the V-shaped pit 160. In this embodiment, by controlling the bandgap energy (Eg5) of the hole injection layer 142 to be higher than the bandgap energy (Eg1) of the well layers 132 and lower than the bandgap energy (Eg2) of the one of the barrier layers 131, it can be ensured that the hole injection layer 142 may fill the V-shaped pit 160 better, thereby reducing the occurrence of leakage current and improving the anti-aging ability of the semiconductor light-emitting device.

In this embodiment, forming the V-shaped pit 160 in the semiconductor stack is beneficial for improving the hole-electron recombination efficiency of the light-emitting layer 130. In addition, by controlling the position of the vertex (A) and the depth of the V-shaped pit 160, and by adjusting the bandgap energy (Eg5) of the hole injection layer 142 to be lower than the bandgap energy (Eg2) of the one of the barrier layers 131, the V-shaped pit 160 can be better filled, which may effectively limit the concentration of the p-type impurity in the light-emitting layer 130, thereby improving the anti-aging performance of the semiconductor light-emitting device.

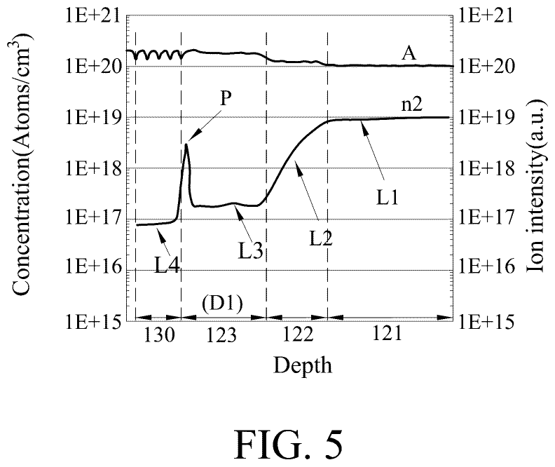

FIG. 5 is a graph showing the relationship between elemental concentration or ion intensity and depth for a portion of a semiconductor light-emitting device according to a third embodiment of the present disclosure. Unlike the graph regarding the semiconductor light-emitting device of the first embodiment shown in FIG. 2, the concentration profile (n2) of the n-type impurity of the semiconductor light-emitting device in this embodiment further includes, in addition to first, second and third segments (L1-L3), a peak segment (P) and a fourth segment (L4), and the peak segment (P) connects the third segment (L3) and the fourth segment (L4). The peak segment (P) may correspond to a region between the third layer 123 and the light-emitting layer 130 in the semiconductor stack. By forming the region with high concentrations of the n-type impurity between the light-emitting layer 130 and the third layer 123, the electrostatic discharge resistance of the semiconductor light-emitting device may be improved. In some embodiments, a peak value of the peak segment (P) is less than 1×10¹⁹ atoms/cm³ and greater than 5×10¹⁷ atoms/cm³. In this embodiment, the peak value is approximately 2×10¹⁸ atoms/cm³. In some embodiments, the peak segment (P) has a full width at half maximum that corresponds to a region between the third layer 123 and the light-emitting layer 130 having a thickness ranging from 5 nm to 50 nm (e.g., from 5 nm to 20 nm). The fourth segment (L4) may correspond to the light-emitting layer 130 in the semiconductor stack, and indicates a concentration of the n-type impurity less than the second concentration of the n-type impurity indicated by the third segment (L3). In some embodiments, the concentration of the n-type impurity indicated by the fourth segment (L4) is less than 1×10¹⁷ atoms/cm³, which allows for better suppression of leakage current.

In this embodiment, by forming the peak segment (P) of the concentration profile of the n-type impurity between the third layer 123 and the light-emitting layer 130, and by controlling a full width at half maximum of the p segment (P), the depletion region between the N-type semiconductor layer 120 and the P-type semiconductor layer 140 may be narrowed, thereby effectively improving the electrostatic discharge resistance of the semiconductor light-emitting device. Furthermore, in a case where the V-shaped pit 160 is formed in the light-emitting layer 130, controlling the concentration of the n-type impurity in the light-emitting layer 130 to be lower than the second concentration of the n-type impurity reduces the likelihood of carrier leakage occurring along a sidewall of the V-shaped pit 160.

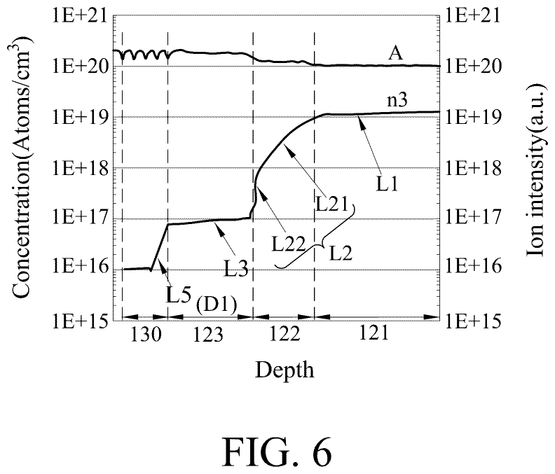

FIG. 6 is a graph showing the relationship between elemental concentration or ion intensity and depth for a portion of a semiconductor light-emitting device according to a fourth embodiment of the present disclosure. Unlike the concentration profile (n1) of the semiconductor light-emitting device of the first embodiment shown in FIG. 2, in the concentration profile (n3) of the n-type impurity of the semiconductor light-emitting device of this embodiment, the second segment (L2), which corresponds to the Z region, includes a first sub-segment (L21) that is connected to the first segment (L1), and a second sub-segment (L22) that is connected to the third segment (L3). A slope of the first sub-segment (L21) is less than a slope of the second sub-segment (L22) (or the slope of the second sub-segment (L22) is greater than the slope of the first sub-segment (L21)); that is, a concentration decrease rate of the n-type impurity shown by the first sub-segment (L21) is less than a concentration decrease rate of the n-type impurity shown by the second sub-segment (L22). In this embodiment, the first sub-segment (L21) indicates a concentration of the n-type impurity ranging from 1×10¹⁸ atoms/cm³ to 1×10¹⁹ atoms/cm³, and the second sub-segment (L22) shows a linear decreasing trend from the first sub-segment (L21) towards the third segment (L3). In addition, along the thickness direction of the semiconductor stack, the first sub-segment (L21) corresponds to a first sub-region of the Z region, and the second sub-segment (L22) corresponds to a second sub-region of the Z region. Furthermore, a thickness of the first sub-region is not less than three times a thickness of the second sub-region. In some embodiments, the thickness of the first sub-region is not less than five times the thickness of the second sub-region. In this embodiment, the first sub-segment (L21) mainly corresponds to the second layer 122, and the second sub-segment (L22) corresponds to an interface between the second layer 122 and the third layer 123. In some embodiments, the second concentration of the n-type impurity indicated by the third segment (L3) is less than or equal to 1×10¹⁷ atoms/cm³. In other embodiments, the concentration profile (n3) of the n-type impurity may further include a fifth segment (L5) that is connected to the third segment (L3), that corresponds to a portion of the light-emitting layer 130, and that indicates a concentration of the n-type impurity in such a portion. In this embodiment, the concentration of the n-type impurity indicated by the fifth segment (L5) decreases linearly in the light-emitting layer 130 and eventually remains at a level of approximately 1×10¹⁶ atoms/cm³.

In this embodiment, firstly, controlling a concentration of the n-type impurity in the second sub-region at a certain level may better facilitate current spreading, so that the photoelectric conversion efficiency of the semiconductor light-emitting layer may be improved; and secondly, reducing the doping concentration of the n-type impurity in the third layer 123 to be less than or equal to 1×10¹⁷ atoms/cm³ may effectively mitigate the risk of leakage current caused by an increased n-type impurity concentration of the second layer 122. By linearly reducing the concentration of the n-type impurity in the light-emitting layer 130 and eventually maintaining the concentration at the level of approximately 1×10¹⁶ atoms/cm³, leakage current may be further suppressed.

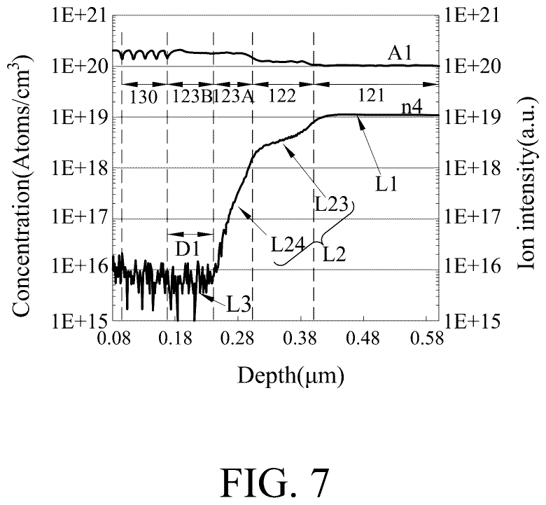

FIG. 7 is a graph showing the relationship between elemental concentration or ion intensity and depth for a portion of a semiconductor light-emitting device according to a fifth embodiment of the present disclosure. Unlike the concentration profile (n1) of the semiconductor light-emitting device of the first embodiment shown in FIG. 2, in the concentration profile (n4) of the n-type impurity of the semiconductor light-emitting device of this embodiment, the second segment (L2), which corresponds to the Z region, includes a third sub-segment (L23) and a fourth sub-segment (L24). A slope of the third sub-segment (L23) is less than a slope of the fourth sub-segment (L24); that is, a concentration decrease rate of the n-type impurity shown by the third sub-segment (L23) is less than a concentration decrease rate of the n-type impurity shown by the fourth sub-segment (L24). In some embodiments, the third sub-segment (L23) indicates a concentration of the n-type impurity greater than or equal to 1×10¹⁸ atoms/cm³ and less than 1×10¹⁹ atoms/cm³, which facilitates current spreading and enhances photoelectric conversion efficiency of the semiconductor light-emitting device. In some embodiments, exhibiting a linear decrease shown by the fourth sub-segment (L24) helps not only to maintain the concentration of the n-type impurity indicated by the second segment at a relatively high level overall, but also to allow the second concentration indicated by the third segment (L3) to be maintained at a relatively low level, thereby enhancing the optoelectronic properties of the semiconductor light-emitting device.

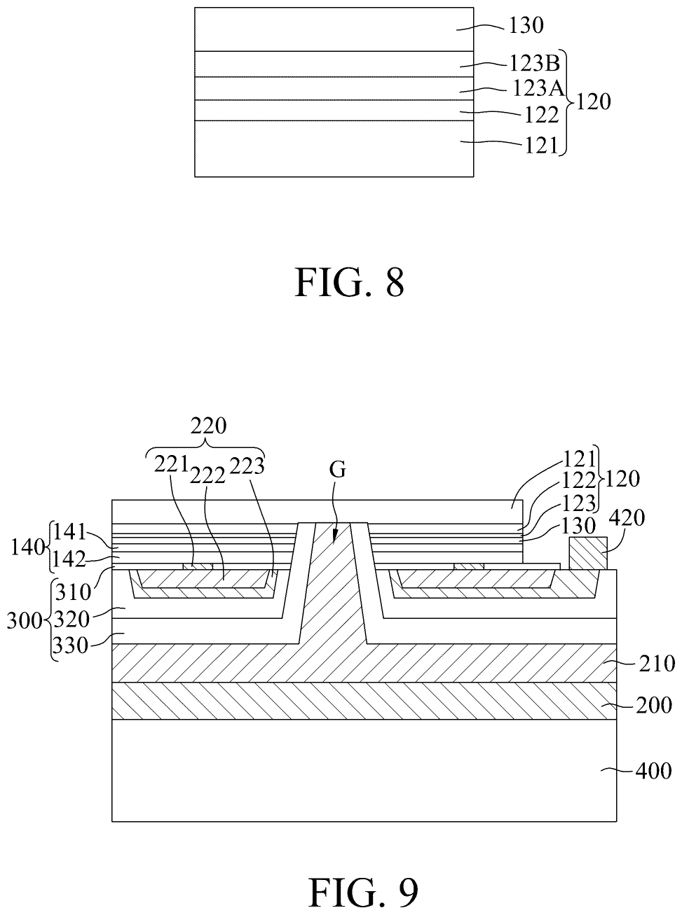

Referring to FIG. 8, in this embodiment, the third layer 123 may be divided into at least a first sublayer 123A (or a first portion 123A) and a second sublayer 123B (or a second portion 123B). The first sublayer 123A is proximate to the second layer 122, and has a concentration of the n-type impurity that gradually decreases from the second layer 122 towards the second sublayer 123B. The second sublayer 123B is proximate to the light-emitting layer 130. In some embodiments, the second layer 122 has a concentration of the n-type impurity which varies along the thickness direction, and a degree of variation in the concentration of the n-type impurity in the second layer 122 is less than a degree of variation in the concentration of the n-type impurity in the first sublayer 123A. Specifically, the first sublayer 123A and the second sublayer 123B are basically composed of the same components, and the main difference therebetween is the concentration of the n-type impurity. Referring to FIGS. 7 and 8 together, the third sub-segment (L23) of the concentration profile (n4) of the n-type impurity indicates the concentration of the n-type impurity in the second layer 122 of the N-type semiconductor layer 120, the fourth sub-segment (L24) indicates a concentration of the n-type impurity in the first sublayer 123A of the third layer 123, and the third segment (L3) exhibits a concentration of the n-type impurity in the second sublayer 123B of the third layer 123. In this embodiment, the second concentration, which is indicated by the third segment (L3), is less than or equal to 5×10¹⁶ atoms/cm³, and the thickness of the Y region of the N-type semiconductor layer 120 that corresponds to the third segment (L3) is not less than 10 nm. In some embodiments, the thickness of the Y region of the N-type semiconductor layer 120 that corresponds to the third segment (L3) ranges from 10 nm to 150 nm, meaning that a thickness of the second sublayer 123B may be greater than or equal to 10 nm and less than or equal to 150 nm. In this embodiment, the second layer 122 has a higher concentration of the n-type impurity, e.g., greater than or equal to 1×10¹⁸ atoms/cm³, so if the thickness of the second sublayer 123B of the third layer 123 is less than 10 nm, the effect of suppressing leakage current will be relatively weak. Meanwhile, the concentration of the n-type impurity in the second sublayer 123B being less than or equal to 5×10¹⁶ atoms/cm³ causes an increase in resistance. If the thickness of the second sublayer 123B exceeds 150 nm, a significant increase in the forward voltage of the semiconductor light-emitting device would occur. In some embodiments, the thickness of the second sublayer 123B ranges from 30 nm to 80 nm.

In this embodiment, the third segment (L3) of the concentration profile (n4) may further correspond to a region of the light-emitting layer 130, where the region of the light-emitting layer 130 has a concentration of the n-type impurity less than or equal to 5×10¹⁶ atoms/cm³. In such a case, a thickness of the region along the thickness direction corresponding to the third segment (L3) is greater than 50 nm and less than 300 nm, so as to suppress leakage current while taking into account the forward voltage of the semiconductor light-emitting device. In other embodiments, by linearly reducing the concentration of the n-type impurity in the first sublayer 123A of the third layer 123, and by finally maintaining a concentration of the n-type impurity in the light-emitting layer 130 at a level of 1×10¹⁶ atoms/cm³, the occurrence of leakage current may be further suppressed.

FIG. 9 is a cross-sectional view of a semiconductor light-emitting device according to a sixth embodiment of the present disclosure. Specifically, the semiconductor light-emitting device is a vertical-structure light-emitting diode. The semiconductor light-emitting device includes, from bottom to top, a conductive substrate 400 and the semiconductor stack disposed above the conductive substrate 400. In some embodiments, a bonding metal layer and/or an insulating dielectric layer may be disposed between the conductive substrate 400 and the semiconductor stack to serve as a connecting layer 200.

The semiconductor stack has a sidewall, and includes a first surface (or a top surface) and a second surface (or a bottom surface) disposed opposite to the first surface. The first surface is a front side of the semiconductor stack, and the second surface is a back side thereof. In addition, the semiconductor stack includes the N-type semiconductor layer 120, the light-emitting layer 130, the electron blocking layer 141, and the hole injection layer 142 arranged sequentially between the first surface and the second surface. The N-type semiconductor layer 120 may have the structure illustrated in FIG. 8, and the concentration distribution of the n-type impurity in the N-type semiconductor layer 120 and the light-emitting layer 130 may be configured with reference to the graph shown in FIG. 7. The semiconductor stack has one or more recesses (G) recessed from the second surface, and each of the recess(es) (G) penetrates at least through the P-type semiconductor layer 140 and the light-emitting layer 130, and into a portion of the first layer 121 of the N-type semiconductor layer 120. Furthermore, the vertical-structure light-emitting diode also includes a first electrical connection layer 210, a second electrical connection layer 220, and an insulation unit 300. The second electrical connection layer 220 includes a transparent conductive layer 221, which contacts the semiconductor stack, a metal reflective layer 222, and a metal connection layer 223. The first electrical connection layer 210 forms a protrusion within the recess(es) (G), and is electrically connected to the N-type semiconductor layer 120. The insulation unit 300 includes a first insulation layer 310, a second insulation layer 320 and a third insulation layer 330. The first electrical connection layer 210 and the second electrical connection layer 220 are electrically isolated from each other by the second insulation layer 320 and the third insulation layer 330. The first electrical connection layer 210 and/or the second electrical connection layer 220 include metal. The conductive substrate 400 serves as a first electrode and is electrically connected to the first electrical connection layer 210. The semiconductor light-emitting device of this embodiment further includes a second electrode 420 which is provided on an upper surface of the second electrical connection layer 220. The first electrode and the second electrode 420 are used to connect to an external circuit. Furthermore, the first insulation layer 310 may be provided between the second electrical connection layer 220 and the semiconductor stack, which is beneficial for improving the optoelectronic performance of the semiconductor light-emitting device.

The present disclosure also provides an embodiment of a light-emitting apparatus which includes a circuit board and at least one of the aforesaid embodiments of the semiconductor light-emitting device, which is disposed on the circuit board. In an embodiment, the semiconductor light-emitting device may be the light-emitting diode of the first embodiment. The light-emitting apparatus has excellent anti-aging properties.

By providing the semiconductor light-emitting device and the light-emitting apparatus including the semiconductor light-emitting device, the problem of leakage current occurring in the semiconductor light-emitting device or the light-emitting apparatus can be eliminated, thereby achieving the purpose of the present disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor light-emitting device, comprising:
a semiconductor stack which includes an N-type semiconductor layer, a light-emitting layer and a P-type semiconductor layer, said N-type semiconductor layer, said light-emitting layer and said P-type semiconductor layer being stacked in such an order in a thickness direction,
wherein at least a part of said semiconductor stack contains an n-type impurity, said n-type impurity having a concentration profile along the thickness direction, said concentration profile including a first segment, a second segment and a third segment, said N-type semiconductor layer having an X region which is distal from said light-emitting layer, a Y region which is proximate to said light-emitting layer, and a Z region which is connected between said X region and said Y region,
wherein said first segment corresponds to said X region and indicates a first concentration of said n-type impurity in said X region, said first concentration of said n-type impurity being greater than or equal to 5×10¹⁸ atoms/cm³,
wherein at least a part of said third segment corresponds to said Y region and indicates a second concentration of said n-type impurity in said Y region, said second concentration of said n-type impurity being less than 1×10¹⁸ atoms/cm³,
wherein said second segment corresponds to said Z region and indicates a third concentration of said n-type impurity in said Z region, said third concentration of said n-type impurity ranging from said first concentration of said n-type impurity to said second concentration of said n-type impurity, and
wherein a thickness of said Y region is greater than or equal to 10 nm.

2. The semiconductor light-emitting device as claimed in claim 1, wherein a part of said third segment corresponds to at least a portion of said light-emitting layer, a concentration of said n-type impurity in said at least a portion of said light-emitting layer being less than or equal to 5×10¹⁷ atoms/cm³.

3. The semiconductor light-emitting device as claimed in claim 2, wherein said third segment corresponds to a region of said semiconductor stack having a thickness greater than or equal to 50 nm and less than 300 nm.

4. The semiconductor light-emitting device as claimed in claim 1, wherein a part of said third segment exhibits a concentration of said n-type impurity less than or equal to 5×10¹⁶ atoms/cm³.

5. The semiconductor light-emitting device as claimed in claim 1, wherein said second segment includes a first sub-segment that is connected to said first segment, and a second sub-segment that is connected to said third segment, a slope of said second sub-segment being greater than a slope of said first sub-segment.

6. The semiconductor light-emitting device as claimed in claim 5, wherein said first sub-segment exhibits a concentration of said n-type impurity ranging from 1×10¹⁸ atoms/cm³ to 1×10¹⁹ atoms/cm³.

7. The semiconductor light-emitting device as claimed in claim 5, wherein said second sub-segment shows a linear decreasing trend from said first sub-segment towards said third segment.

8. The semiconductor light-emitting device as claimed in claim 1, wherein said concentration profile further includes a peak segment and a fourth segment, said peak segment connecting said third segment and said fourth segment, and having a peak value less than 1×10¹⁹ atoms/cm³ and greater than 5×10¹⁷ atoms/cm³.

9. The semiconductor light-emitting device as claimed in claim 8, wherein said peak segment has a full width at half maximum that corresponds to a region of said semiconductor stack having a thickness ranging from 5 nm to 50 nm.

10. The semiconductor light-emitting device as claimed in claim 8, wherein said second concentration of said n-type impurity is not greater than 5×10¹⁷ atoms/cm³, said fourth segment exhibiting a concentration of said n-type impurity less than 1×10¹⁷ atoms/cm³.

11. The semiconductor light-emitting device as claimed in claim 1, wherein said N-type semiconductor layer includes a first layer, a second layer, and a third layer, and wherein said first layer is an Alₓ₁Ga₁₋ₓ₁N semiconductor layer having a doping concentration of said n-type impurity greater than or equal to 5×10¹⁸ atoms/cm³, said second layer is an Alₓ₂Ga₁₋ₓ₂N semiconductor layer, and said third layer is a superlattice structure containing Alₓ₃Ga₁₋ₓ₃N, where x1<x2<x3, said doping concentration of said n-type impurity in said first layer being greater than a doping concentration of said n-type impurity in said second layer.

12. The semiconductor light-emitting device as claimed in claim 11, wherein a bandgap energy of said third layer is higher than a bandgap energy of said light-emitting layer, and said light-emitting layer emits light having a wavelength ranging from 340 nm to 425 nm.

13. The semiconductor light-emitting device as claimed in claim 1, wherein said P-type semiconductor layer includes an electron blocking layer and a hole injection layer, said electron blocking layer being disposed between said light-emitting layer and said hole injection layer, and having at least one V-shaped pit that extends into said light-emitting layer and has a vertex pointing towards said light-emitting layer, said hole injection layer filling said at least one V-shaped pit.

14. The semiconductor light-emitting device as claimed in claim 13, wherein said light-emitting layer includes a quantum well structure having a barrier layer and a well layer, a bandgap energy of said hole injection layer being lower than a bandgap energy of said barrier layer.

15. A semiconductor light-emitting device, comprising:
a semiconductor stack which includes an N-type semiconductor layer, a light-emitting layer, and a P-type semiconductor layer, said N-type semiconductor layer, said light-emitting layer and said P-type semiconductor layer being stacked in such an order in a thickness direction,
wherein said N-type semiconductor layer includes a first layer, a second layer, and a third layer, said first layer being an Alₓ₁Ga₁₋ₓ₁N semiconductor layer that has a first concentration of an n-type impurity greater than or equal to 5×10¹⁸ atoms/cm³, said third layer being a superlattice structure that contains Alₓ₃Ga₁₋ₓ₃N, being proximate to said light-emitting layer, having a second concentration of said n-type impurity less than 1 ×10¹⁸ atoms/cm³, and having a thickness greater than or equal to 10 nm, said second layer being an Alₓ₂Ga₁₋ₓ₂N semiconductor layer that is disposed between said first layer and said third layer, and having a concentration of said n-type impurity less than said first concentration of said n-type impurity and greater than said second concentration of said n-type impurity.

16. The semiconductor light-emitting device as claimed in claim 15, wherein x1<x2<x3.

17. The semiconductor light-emitting device as claimed in claim 15, wherein said second concentration of said n-type impurity is less than or equal to 1×10¹⁷ atoms/cm³.

18. The semiconductor light-emitting device as claimed in claim 15, wherein a concentration of said n-type impurity in said light-emitting layer is less than or equal to 5×10¹⁷ atoms/cm³.

19. The semiconductor light-emitting device as claimed in claim 15, wherein said third layer includes a first portion and a second portion, said first portion being proximate to said second layer and having a concentration of said n-type impurity that gradually decreases from said second layer towards said second portion.

20. The semiconductor light-emitting device as claimed in claim 19, wherein said second layer has a concentration of said n-type impurity which varies along said thickness direction, and a degree of variation in said concentration of said n-type impurity in said second layer is less than a degree of variation in said concentration of said n-type impurity in said first portion.

21. The semiconductor light-emitting device as claimed in claim 15, wherein said P-type semiconductor layer includes an electron blocking layer and a hole injection layer, said electron blocking layer being disposed between said light-emitting layer and said hole injection layer, and having at least one V-shaped pit that extends into said light-emitting layer and has a vertex pointing towards said light-emitting layer, said hole injection layer filling said at least one V-shaped pit.

22. The semiconductor light-emitting device as claimed in claim 21, wherein said light-emitting layer emits light having a wavelength ranging from 340 nm to 425 nm, a bandgap energy of said hole injection layer being lower than a bandgap energy of said light-emitting layer.

23. A semiconductor light-emitting device, comprising:
a semiconductor stack which includes an N-type semiconductor layer, a light-emitting layer and a P-type semiconductor layer stacked in such an order along a thickness direction, said light-emitting layer emitting light having a wavelength ranging from 340 nm to 425 nm;
wherein said semiconductor stack has an n-type impurity that has a concentration profile along the thickness direction, said concentration profile corresponding to a region from said N-type semiconductor layer toward said P-type semiconductor layer, and indicating a concentration of said n-type impurity in said region, said concentration of said n-type impurity being less than or equal to 5×10¹⁶ atoms/cm³, said region having a thickness greater than or equal to 50 nm and less than 300 nm.

24. The semiconductor light-emitting device as claimed in claim 23, wherein said P-type semiconductor layer includes an electron blocking layer and a hole injection layer, said electron blocking layer being disposed between said light-emitting layer and said hole injection layer, and having at least one V-shaped pit that extends into said light-emitting layer and has a vertex pointing towards said light-emitting layer, said hole injection layer filling said at least one V-shaped pit.

25. The semiconductor light-emitting device as claimed in claim 23, wherein said N-type semiconductor layer includes a first Alₓ₁Ga₁₋ₓ₁N semiconductor layer having a first concentration of said n-type impurity greater than or equal to 5×10¹⁸ atoms/cm³, a second Alₓ₂Ga₁₋ₓ₂N semiconductor layer, and a superlattice structure containing Alₓ₃Ga₁₋ₓ₃N, where x1 <x2 <x3, said superlattice structure having a concentration of said n-type impurity which varies along said thickness direction and decreases to less than 5×10¹⁶ atoms/cm³ at a side of said superlattice structure proximate to said light-emitting layer.

26. A light-emitting apparatus, comprising a semiconductor light-emitting device as claimed in claim 1.
